(19) United States
(12) Patent Application Publication
(10) Pub. No.: US 2009/0027857 A1
(43) Pub. Date: Jan. 29, 2009

(54) Heat spreader constructions, intergrated circuitry, methods of forming heat spreader constructions, and methods of forming integrated circuitry

(76) Inventors: Nancy F. Dean, Ann Arbor, MI (US); Ignatius J. Rasiah, Singapore (SG)

Correspondence Address: BUCHALTER NEMER, 18400 VON KARMAN AVE., SUITE 800, IRVINE, CA, 92612, US

(21) Appl. No.: 10/585,275

(22) PCT Filed: Mar. 29, 2005
(86) PCT No.: PCT/US2005/010550

§ 371 Date: Jul. 5, 2006

Related U.S. Application Data
(60) Provisional application No. 60/557,889, filed on Mar. 30, 2004.

(51) Int. Cl. H05K 7/20; B23P 6/00

(52) U.S. Cl. 361/709; 29/890.032

(57) ABSTRACT

The invention includes a heat spreader having a base which has a perimeter surface surrounding a heat-receiving region. A frame portion interfaces the perimeter surface and has an opening traversing a thickness of the frame. The invention includes a method of forming a heat spreader construction by forming a base portion having a perimeter region surrounding a heat-receiving surface. An independent frame portion is joined to the base portion. The invention includes integrated circuitry having a heat spreader construction in thermal communication with a heat-generating device. The heat spreader has a base having a heat-receiving surface and a perimeter surface which interfaces a frame portion. The invention includes methodology for forming integrated circuitry which includes providing an integrated circuitry board having a heat generating device mounted thereon, and providing a multi-part heat spreader in thermal communication with the heat-generating device.

### TECHNICAL FIELD

The invention pertains to heat spreader constructions, methods of forming heat spreaders, integrated circuitry incorporating heat spreaders in accordance with the invention, and methodology for forming such integrated circuitry.

### BACKGROUND OF THE INVENTION

Thermal management in electronic devices is important for proper device performance. Thermal management components such as heat sinks and heat spreaders are utilized to decrease potential negative impacts of heat-generating components in a wide range of electronic devices by aiding in the transfer of heat to the ambient environment.

One area of particular importance for developing thermal management technology is integrated circuitry. With advances in device and integrated circuit (IC) technology, faster and more powerful devices are being developed. Faster switching and an increase in transistors per unit area in turn lead to increased heat generation. Packaging for these devices can typically incorporate a heat spreader which assists in heat transfer from the device to a heat sink. Heat dissipation from the devices can have a large role in device stability and reliability.

Thermal management and removal of heat can be particularly important and challenging in the area of flip-chip technology which is utilized for connecting high performance integrated circuit devices to substrates. Heat spreaders can typically be utilized in flip-chip technology to provide a lower thermal resistance pathway between the chip and ultimate heat sink. Various materials such as copper and aluminum alloys have been utilized for flip-chip heat spreader applications. In particular instances, materials such as carbon-carbon composites or diamond can be advantageously utilized for heat spreader applications due to their exceptional thermal conductivity. Diamond and carbon-carbon composite heat spreaders can have greatly enhanced thermal transfer rates relative to alternative materials having lower thermal conductivity. Diamond heat spreaders can also allow a better thermal expansion match between the chip and packaging components. However, due to the expense of diamond materials and the relative difficulty in fabricating conventional heat spreader configurations utilizing diamond or composite carbon-carbon materials, heat spreaders for flip-chip and other microelectronic applications fabricated from these materials can be cost prohibitive.

Thermal management for flip-chip and other microelectronic devices can affect device lifetime and performance. Improved methods and configurations for heat transfer away from such microelectronic devices can play an important role in allowing development of faster and more powerful devices. Accordingly, new configurations for diamond, carbon composite and alternative thermal control material heat spreaders are desired for flip-chip technology and other integrated circuitry as well as other electronic device applications.

### SUMMARY OF THE INVENTION

In one aspect the invention encompasses a heat spreader construction. The construction includes a base portion having a heat spreading surface, including a heat-receiving region and a perimeter surface surrounding the heat-receiving region. The base portion comprises a first material. The construction additionally includes a frame portion comprising a second material, which interfaces the perimeter surface of the base portion. The frame portion has a thickness and has an opening traversing the thickness.

In one aspect the invention encompasses a method of forming a heat spreader construction. The method includes forming a base portion of a first material, the base portion having a first surface including a perimeter region surrounding a heat-receiving surface. A frame portion comprising a second material is formed, and the frame portion is joined to the base portion.

In one aspect the invention encompasses integrated circuitry comprising a heat-generating device and a heat spreader construction in thermal communication with the heat-generating device. The heat spreader construction includes a base portion having a heat spreading surface disposed in heat-receiving relation relative to the heat-generating device. The base portion has a perimeter surface surrounding the heat spreading surface which interfaces a frame portion comprised by the heat spreader construction. The frame portion has a thickness and has an opening which traverses the thickness.

In one aspect the invention encompasses methodology for forming integrated circuitry which includes providing an integrated circuitry board having a heat generating device mounted thereon, and providing a heat spreader in thermal communication with the heat generating device. The heat spreader includes a base portion comprising a first material and a frame portion comprising a second material. The base portion has a heat-receiving surface and a perimeter region around the heat-receiving surface. The frame portion interfaces the perimeter region of the base portion.

### BRIEF DESCRIPTION OF THE DRAWINGS

Preferred embodiments of the invention are described below with reference to the following accompanying drawings.

FIG. 1 is an isometric view of an exemplary prior art heat spreader configuration.

FIG. 2 is an isometric view of a heat spreader in accordance with an aspect of the present invention.

FIG. 3 is an exploded isometric view of the heat spreader shown in FIG. 2.

FIG. 4 is an alternate isometric view of the heat spreader shown in FIG. 2.

FIG. 5 is a cross-sectional side view taken along line 5-5 of FIG. 4.

FIG. 6 is a side view of a heat spreader plate in accordance with an alternative aspect of the invention.

FIG. 7 is a side view of an assembled heat spreader containing the heat spreader plate shown in FIG. 6.

FIG. 8 is a cross-sectional fragmentary view of integrated circuitry in accordance with an aspect of the invention.

### DETAILED DESCRIPTION OF THE PREFERRED EMBODIMENTS

One aspect of the invention is to develop methodology and heat spreader configurations to allow cost effective manufacture of heat spreaders capable of maintaining the integrity and performance of electronic and microelectronic devices. In particular, heat spreader configurations of the invention allow materials with high heat conductivity to be localized in appropriate heat-receiving/dissipating areas while replacing less critical regions of the spreader with less expensive and/or more easily fabricated materials.

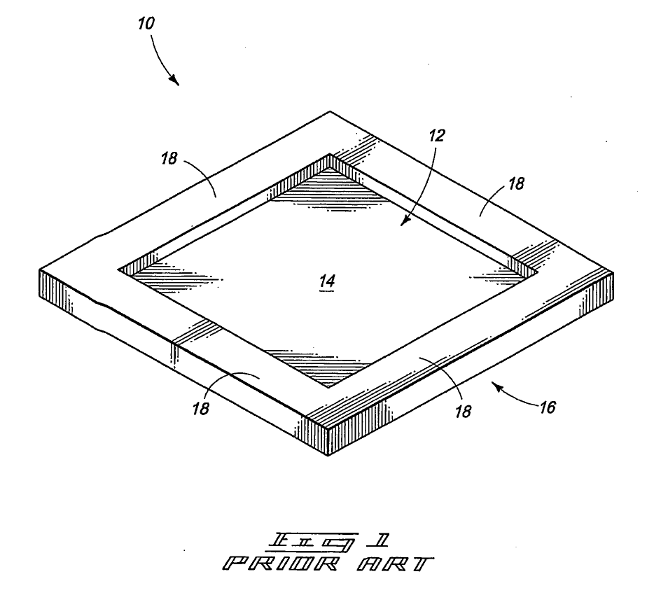

A drawback of conventional heat spreader technology is described with reference to FIG. 1. FIG. 1 shows an exemplary prior art “lid” type heat spreader 10 which is comprised of a single piece of material. The single piece heat spreader shown in FIG. 1 can typically be fabricated by, for example, stamping, coining and/or machining from a single sheet of material.

Heat spreader 10 can have an opening, cavity or recess 12 having a base surface 14 and can have an opposing back surface 16. For use in flip-chip applications, a heat spreader such as heat spreader 10 shown in FIG. 1 can be disposed over and/or in heat-receiving relation relative to a flip-chip (not shown). Base surface 14 can function as a heat-receiving surface relative to a surface of the flip-chip and thereby allow heat dissipation from the flip-chip through spreader 10.

In application, where conventional heat spreader 10 is disposed over a microelectronic device, an upper surface 18 can interface an integrated circuitry board, or package substrate (not shown). In particular applications, opposing face 16 can be disposed interfacing an appropriate heat sink (not shown).

The exemplary conventional heat spreader 10 shown in FIG. 1 can be formed from any of a variety of known materials, including but limited to, copper, copper alloys, diamond, aluminum, aluminum alloys, carbon-carbon composite materials, copper composites, aluminum silicon carbide, copper-tungsten, copper-molybdenum-copper, silicon carbide, or diamond composite materials. Due to the single piece configuration of heat spreader 10, fabrication of the heat spreader and formation of form cavity 12 can be time consuming, difficult and/or expensive based upon the particular material utilized. Where recess 12 is formed by machining out an opening within a material, such can result in waste of the material from such machined out portion.

Where materials having limited ductility are utilized for heat spreader 10, formation of recess 12 using stamping, coining or other plastic deformation methods may not be feasible. Where the material utilized is expensive, such as for example, diamond, the cost of forming opening 12 and the additional waste of material which is removed to form such opening can be cost prohibitive.

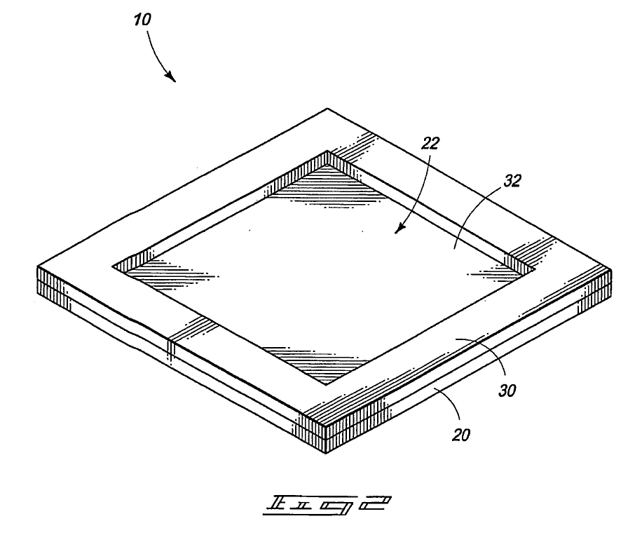

A heat spreader configuration in accordance with the present invention is discussed with reference to FIGS. 2-5. Referring initially to FIG. 2, such shows a heat spreader 10 having a first portion or ‘base’ portion 20 and a second independently formed raised ‘frame’ portion 30. Heat spreader 10 can have a heat-spreading surface 22 which can ultimately be disposed interfacing a “hot device” surface, where the term “hot device” refers to a heat-generating device from which heat is to be drawn away.

Referring to FIG. 3, such shows an exploded view depicting the two separate pieces 20 and 30 which can together form spreader 10. As shown, surface 22 of base piece 20 can have an interior region 23 which can be referred to as a heat-receiving surface, at least a portion of which will interface a hot device. Base piece 20 also has a perimeter region 24 of surface 22 which interfaces independent frame piece. 30.

Frame portion 30 of heat spreader 10 can be described as having a first interface surface 34 which will be disposed interfacing the base portion, and a second opposing interface surface 36 which can interface, for example a circuit board. When the two pieces 20 and 30 are joined as shown in FIG. 2, piece 30 can frame heat-receiving surface 23 within an opening 32 which transverses frame piece 30.

Base piece 20 can comprise any heat spreading material and can preferably comprise a material with a relatively low coefficient of thermal expansion and high thermal conductivity. Although not limited to any particular coefficient of thermal expansion, appropriate materials for base piece 20 can preferably have a thermal expansion coefficient of less than about 9 ppm/K, and in particular applications can preferably have a coefficient of thermal expansion of less than about 6 ppm/K. Thermal conductivity of appropriate materials is also not limited to particular values. In particular applications, materials used for base piece 20 can preferably have a thermal conductivity of at least 300 W/mK, and in particular instances can preferably be greater than 400 W/mK. Exemplary materials which can be utilized for base piece 20 include but are not limited to copper, copper alloys (e.g., Cu—Ni), aluminum, aluminum alloys, composite carbon-carbon materials, SiC, graphite, carbon, diamond and diamond composites (i.e. diamond composites comprising SiC, graphite or carbon), and combinations thereof.

Base portion 20 and frame portion 30 can be formed of the same material or can have differing compositions relative to one another. Because base portion 20 is the primary dissipating region of the heat spreader, second portion 30 can in particular applications comprise a less expensive material, a more easily fabricated material and/or a material with a lower thermal conductivity relative to base portion 20. Accordingly, the cost of materials for the two piece heat spreader in accordance with the invention can be significantly less than conventional single piece heat spreader configurations.

Frame portion 30 can be formed by, for example, stamping, coining and/or machining. Exemplary materials which can be utilized for frame portion 30 can be, for example, copper, copper alloys, carbon composite, a luminum, aluminum alloys, diamond, ceramic, molybdenum, tungsten, KOVAR® (Westinghouse Electric and Manufacturing Company, Pittsburgh Pa.), alloy 42, SiC, carbon, graphite, diamond composites (see above, for example), and combinations thereof. Alternatively or in addition to these materials, frame portion 30 can comprise an appropriate heat-stable polymer material.

Although parts 20 and 30 are shown having approximately equal thickness, it is to be understood that the invention encompasses any relative thicknesses. The thickness of part 30 can depend upon the thickness of an interfacing hot device. Frame part 30 can preferably have a thickness which allows clearance of surface 22 when spreader 10 is disposed over and in heat-receiving relation relative to a device, with frame surface 36 interfacing a circuit board (discussed below). The thickness of base portion 20 can depend on a number of factors including, the amount of heat generated by the hot device, the heat spreading material(s) utilized and the coefficients of thermal expansion of such material(s).

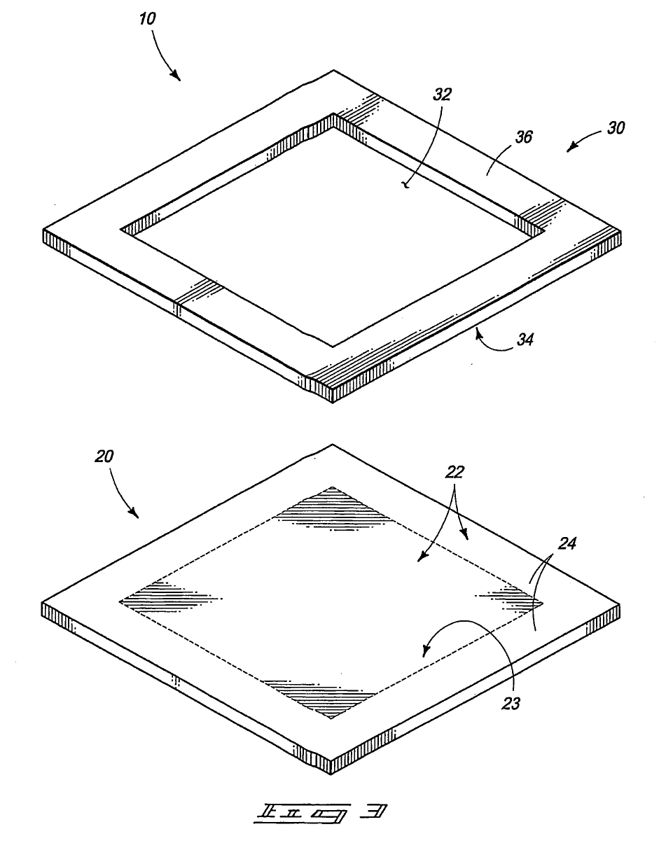

Referring to FIG. 4, such shows an alternative view of heat spreader 10 rotated 180° relative to the view shown in FIG. 2. As shown in FIG. 4, a backside 26 of base piece 20 can oppose heat spreading surface 22 (FIG. 2). As additionally shown in FIG. 4, base part 20 can be joined to frame portion 30 by an interface material 40 disposed between the interfacing surfaces of the two pieces. Material 40 can be, for example, an adhesive or solder. Alternatively, pieces 20 and 30 can be joined in an absence of interfacing material by, for example, diffusion bonding or other direct bonding techniques.

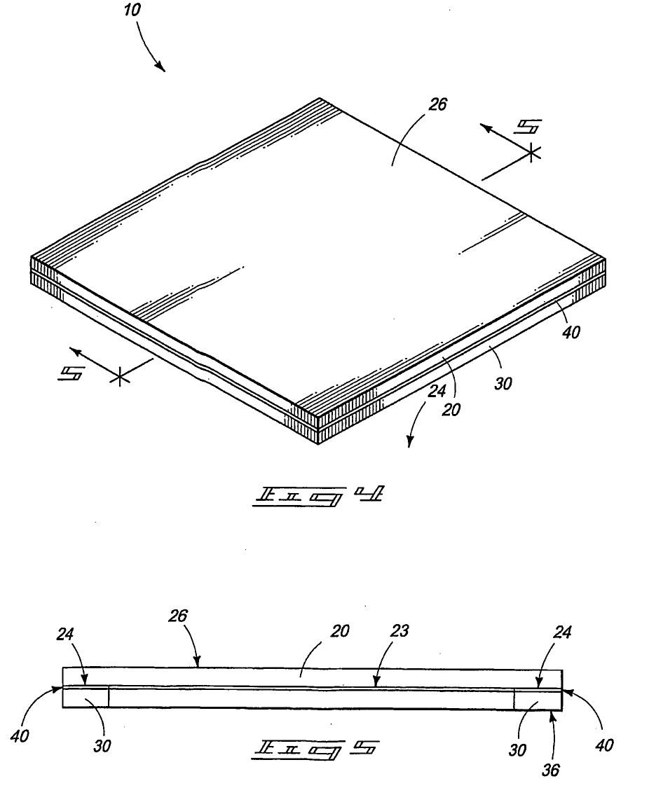

Referring to FIG. 5, such depicts a cross-section of the two part heat spreader taken along line 5-5 of FIG. 4. As shown in FIG. 5, interface material 40 can be disposed between the perimeter region 24 of base portion 20 and interfacing surface 34 of frame portion 30.

Referring to FIG. 6, in particular applications base piece 20 can comprise a heat spreader material 27 which can be any of the materials discussed above with respect to base piece 20, and can additionally comprise a coating material 28. Coating material 28 can cover an entirety of surface 22. Alternatively, material 28 can cover one or more portions of surface 22 such as, for example, perimeter surfaces 24 (shown in FIG. 3) which will interface frame portion 30.

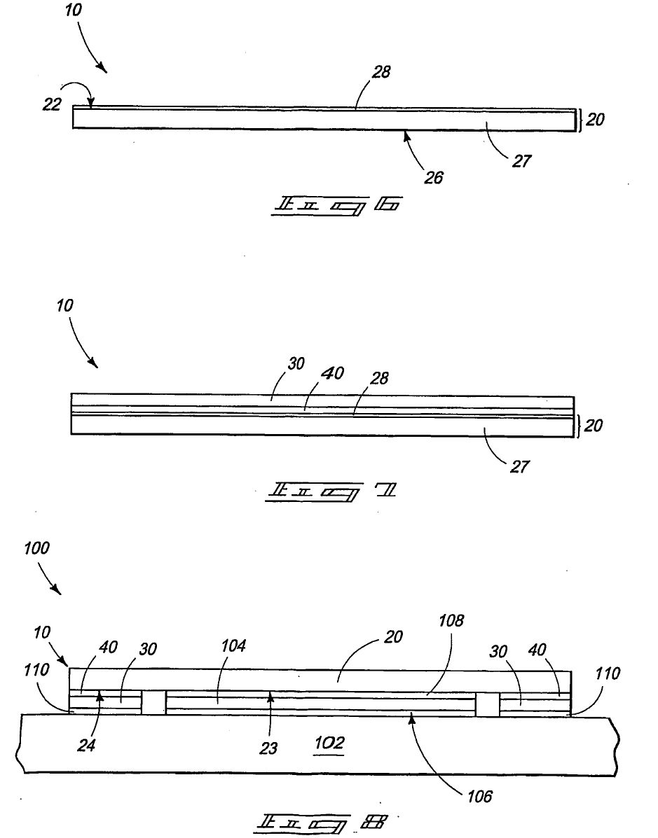

FIG. 7 shows assembled two-piece heat spreader 10 having coating material 28 disposed between interface material 40 and heat spreader material 27. Coating material 28 can comprise, for example, a metal or metallic material. In applications where heat spreader material 27 is difficult to solder (e.g., diamond), coating material 28 can be a metallized layer deposited over the diamond to allow base portion 20 to be soldered to frame portion 30. In one embodiment base portion 20 can comprise a diamond material 27 and a metallized coating 28 which can be, for example, gold. Interface material 40 can be a solder material which bonds to metallized layer 28 and frame portion 30.

Referring again to FIG. 4, heat spreader 10 can be substantially square as depicted. It is to be understood, however, that the invention encompasses alternative heat spreader shapes such as, for example, circular, rectangular, etc., including irregular shapes. Base portion 20 and frame portion 30 can be fabricated accordingly. The shape of heat spreader 10 can of course depend upon the shape of an underlying heat-generating device.

In addition to the single piece base portion depicted in the figures, the invention also contemplates utilizing a plurality of pieces to form base plate 20 (not shown). Where multiple parts form base plate 20, the parts can comprise the same material or different materials. For example, a material such as diamond can be localized to a portion of plate 20 which will interface a ‘hot spot’ or a particularly hot portion of a device, while surrounding parts or parts of plate 20 more remote from the hot spot are formed from a less expensive material and/or a material with a lower coefficient of thermal expansion.

Frame part 30 can also comprise multiple pieces and/or multiple materials (not shown). Additionally, frame portion can be discontinuous, covering only a portion of perimeter region 24 of base plate 20. For example, frame portion 30 can be fragments or spaced blocks along perimeter region 24 sufficient to provide clearance and support for base plate 20 when disposed over a heat-generating device.

It is to be additionally noted that although the heat spreader of the invention is discussed as having a single recessed compartment (i.e. the recess formed by opening 32, as shown in FIG. 2) it is to be understood that frame portion 30 can be fabricated to have a plurality of compartments such that a single heat spreader can cover a plurality of individually framed devices (not shown). Alternatively, a heat spreader in accordance with the invention can be configured to cover a plurality of devices within a single framed compartment.

Referring to FIG. 8, such shows integrated circuitry 100 comprising heat spreader 10 in accordance with the invention disposed over a single microelectronic device 104. Device 104 can be, for example, a flip-chip mounted on integrated circuitry board 102 utilizing, for example, a solder material 106. An interface material 110 can be provided between heat spreader 10 and board 102 in order to mount the heat spreader to the circuitry board. Material 110 can be, for example, an interface adhesive or solder material.

A second interface material 108 can be provided between device 104 and heat spreader 20. Such material can be, for example, a thermal interface material such as thermal grease, phase change materials, thermal gels, indium, indium alloys, metallic thermal interface materials or other known interface materials. Typically, material 108 will cover only a portion of surface 23 which will overlie or interface a heat-generating device, as illustrated in FIG. 8. However in alternative aspects, material 108 can cover an entirety of surface 23, or portions of surface 23 which are not interfacing a heat generating device. It is also to be understood that the sizes of the heat spreader and surface 23 relative to heat-generating device shown in FIG. 8 are for illustrative purposes and alternative relative sizes are contemplated. In particular applications, the size of surface 23 relative to the heat-generating device will be much greater than depicted in FIG. 8.

In particular applications, surface 26 of heat spreader 10 can interface an ultimate heat sink (not shown). An appropriate heat sink can comprise any appropriate heat sink material and configuration known to those skilled in the art or yet to be developed.

Heat spreader configurations of the invention can provide effective thermal management at lower cost and/or ease of fabrication relative to conventional heat spreaders.

Methodology of the invention includes methods of forming the heat spreader constructions described above and methods of incorporating such heat spreader constructions into integrated circuitry. Formation of heat spreader constructions in accordance with the invention can comprise machining or otherwise fabricating a base plate or base portion 20 and a frame portion 30 such as those depicted in FIG. 3. Appropriate materials for use during fabrication include those materials discussed above with respect to the base portion and frame portion. The base portion and the frame portion can be formed of identical materials or can comprise materials of differing composition.

Base portion 20 can be joined to frame portion 10 by, for example, diffusion bonding such that interfacing surface 34 of frame 30 is in direct physical contact with perimeter region 24 of base portion 20 such as depicted in FIG. 2. Alternatively, the frame portion can be joined to the base portion utilizing methodology such as soldering or attaching utilizing application of an appropriate adhesive material.

Methodology utilized for forming a heat spreader construction in accordance with the invention can additionally include providing a coating material 24 over a portion or over an entirety of heat spreader surface 22 as shown in FIGS. 4 and 5. Coating 40 can comprise any of the coating materials discussed above. Coating 40 can be applied to all or a desired portion of surface 22 utilizing any appropriate coating methodology. In particular applications, for example where coating material 40 is utilized to assist attachment or joining the base portion with the frame portion, material 40 can be utilized to coat only perimeter region 24 or portions thereof and can accordingly be applied only to such perimeter region. The base portion and frame portion can subsequently be joined utilizing any of the joining techniques discussed above.

Methodology in accordance with the invention further includes incorporating heat spreader constructions of the invention into integrated circuitry. Such methodology can include providing an integrated circuitry board. A heat-generating device, such as for example, a flip-chip can be mounted on the circuitry board either prior to or at the time of mounting the heat spreader. A heat spreader such as any of the constructions described above is provided to be in thermal communication with the heat generating device. The providing can include mounting the heat spreader to the circuitry board. Such mounting can utilize an adhesive and/or a solder, for example. In particular applications, a thermal interface material can be provided between the heat-generating device and the heat-receiving surface. Such thermal interface material can be, for example, any of the thermal interface materials described above.

The invention claimed is:

1. A heat spreader construction comprising:
a base portion having a heat spreading surface comprising a heat-receiving region and a perimeter surface surrounding the heat-receiving region, the base portion comprising a first material; and
a frame portion comprising a second material and interfacing the perimeter surface, the frame portion having a thickness and having an opening traversing the thickness.

2. The heat spreader construction of claim 1 wherein the first material comprises at least one member of the group consisting of copper, copper alloys, aluminum, aluminum alloys, composite carbon-carbon materials, SiC, carbon, graphite, diamond, diamond composite materials, and combinations thereof.

3. The heat spreader construction of claim 1 wherein the second material comprises at least one member of the group consisting of copper, copper alloys, aluminum, aluminum alloys, composite carbon materials, diamond, ceramic materials, molybdenum, tungsten, KOVAR®, and heat-stable polymer materials.

4. The heat spreader construction of claim 1 further comprising an interface material disposed between the frame portion and the base portion.

5. The heat spreader construction of claim 4 wherein the interface material comprises a member of the group consisting of an adhesive material and a solder material.

6. The heat spreader construction of claim 1 wherein the first material has a thermal conductivity of greater than 300 W/mk.

7. The heat spreader construction of claim 1 wherein the first material has a thermal conductivity of greater than 400 W/mk.

8. The heat spreader construction of claim 1 wherein the first material has a coefficient of thermal expansion of less than 9 ppm/K.

9. The heat spreader construction of claim 1 wherein the first material has a coefficient of thermal expansion of less than 6 ppm/K.

10. The heat spreader construction of claim 1 wherein the frame portion is in direct physical contact with the base portion.

11. The heat spreader construction of claim 10 wherein the base portion and the frame portion are joined by a diffusion bond.

12. The heat spreader construction of claim 1 further comprising a coating material over at least a portion of the heat spreading surface.

13. The heat spreader construction of claim 1 further comprising a coating material over at least a portion of the perimeter surface.

14. The heat spreader construction of claim 13 wherein the coating material is a metallic material.

15. A method of forming a heat spreader construction, comprising:
forming a base portion comprising a first material and having a first surface comprising a perimeter region surrounding a heat-receiving surface;
forming a frame portion comprising a second material; and
joining the base portion and the frame portion.

16. The method of claim 15 wherein the joining comprises attaching the frame portion and the perimeter region, the attaching comprising at least one of soldering, diffusion bonding and application of an adhesive material.

17. The heat spreader construction of claim 15 wherein the first material comprises at least one member of the group consisting of copper, copper alloys, aluminum, aluminum alloys, composite carbon-carbon materials and diamond.

18. The heat spreader construction of claim 15 wherein the second material comprises at least one member of the group consisting of copper, copper alloys, aluminum, aluminum alloys, composite carbon materials, diamond, ceramic materials, molybdenum, tungsten and KOVAR®.

19. The method of claim 15 further comprising applying a metallic coating material over at least a portion of the first surface prior to the joining.

20. Integrated circuitry comprising:
a heat-generating device; and
a heat spreader construction in thermal communication with the heat-generating device, the heat spreader construction comprising:
a base portion having a heat spreading surface disposed in heat-receiving relation relative to the heat-generating device, the base portion having a perimeter surface surrounding the heat spreading surface; and
a frame portion interfacing the perimeter surface, the frame portion having a thickness and having an opening traversing the thickness.

21. The integrated circuitry of claim 20 wherein the heat-generating device is a flip-chip.

22. The integrated circuitry of claim 20 further comprising a circuitry board, wherein the heat spreader is mounted to the circuitry board with an interface material comprising at least one of an adhesive and a solder.

23. The integrated circuitry of claim 20 further comprising an interface material disposed between the heat-generating device and the heat spreading surface.

24. The integrated circuitry of claim 20 further comprising a heat-sink in thermal communication with the heat spreader.

25. A method of forming integrated circuitry comprising:
providing an integrated circuitry board having a heat-generating device mounted thereon;
providing a heat spreader in thermal communication with the heat-generating device, the heat spreader comprising:
a base portion comprising a first material, the base portion having a heat-receiving surface and a perimeter region around the heat-receiving surface; and
a frame portion comprising a second material interfacing the perimeter region.

26. The method of claim 25 further comprising mounting the heat-spreader to the circuitry board utilizing at least one of an adhesive and a solder.

27. The method of claim 25 wherein the heat-generating device is a flip-chip.

28. The method of claim 25 further comprising providing a thermal interface material between the heat-generating device and the heat-receiving surface, the thermal interface material being selected from the group consisting of thermal grease, metallic thermal interface materials, phase-change materials, thermal gels, and indium alloys.
